(19) United States
(12) Patent Application Publication
(10) Pub. No.: US 2024/0096771 A1
(43) Pub. Date: Mar. 21, 2024

(54) WAFER BASED MOLDED FLIP CHIP ROUTABLE IC PACKAGE

(71) Applicant: Texas Instruments Incorporated, Dallas, TX (US)

(72) Inventors: Osvaldo Lopez, Annandale, PA (US); Salvatore Pavone, Houston, TX (US); Sreenivasan Koduri, Dallas, TX (US)

(21) Appl. No.: 17/946,109

(22) Filed: Sep. 16, 2022

(51) Int. Cl. H01L 23/498; H01L 23/00; H01L 25/16

(52) U.S. Cl. CPC H01L 23/49805; H01L 23/49838; H01L 23/49894; H01L 24/16; H01L 24/81; H01L 24/96; H01L 24/97; H01L 25/165; H01L 23/3738; H01L 2224/16227; H01L 2224/81815; H01L 2224/95001

(57) ABSTRACT

An electronic device includes a multilevel metallization structure, a semiconductor die, and a package structure. The multilevel metallization structure has multiple levels of conductive metal traces and vias and polyimide insulator material, including a first level along a first side and a final level along a second side. The first level includes conductive metal leads with exposed surfaces along the first side, and the final level includes conductive metal pads with exposed surfaces along the second side. The semiconductor die is flip chip attached to the first side of the multilevel metallization structure with conductive features connected to respective conductive metal pads of the final level of the multilevel metallization structure, and the package structure encloses the semiconductor die and portions of the first side of the multilevel metallization structure.

### BACKGROUND

Electronic systems often require higher circuit density and circuit components with smaller form factors and fine pitch lead spacing for advanced end equipment applications including automotive systems. Small packages such as quad flat no-lead (QFN) devices have a semiconductor die and a metal lead frame with leads along four lateral sides. Reduced semiconductor die terminal spacing and higher 10 counts can exceed the signal routing capability of conventional interconnect substrates. Improved electronic device packages are desirable to support fine lines and spacing to allow routing of leads and interconnect substrate lines to semiconductor die bumps or terminals.

### SUMMARY

In one aspect, an electronic device includes a multilevel metallization structure, a semiconductor die, and a package structure that encloses the semiconductor die and portions of the first side of the multilevel metallization structure. The multilevel metallization structure has multiple levels of conductive metal traces and vias and polyimide insulator material, including a first level along a first side and a final level. The first level includes conductive metal leads with exposed surfaces along the first side, and the final level includes conductive metal pads with exposed surfaces along the second side. The semiconductor die is flip chip attached to the first side of the multilevel metallization structure with conductive features soldered to respective conductive metal pads of the final level of the multilevel metallization structure.

In another aspect, an electronic device includes a semiconductor substrate, a multilevel metallization structure, a semiconductor die, and a package structure that encloses the semiconductor die and portions of the first side of the multilevel metallization structure. The semiconductor substrate has conductive metal leads with exposed surfaces along a substrate side. The multilevel metallization structure has multiple levels of conductive metal traces and vias and polyimide insulator material, including a first level along a first side and a final level along a second side. The first level includes conductive structures that contact respective ones of the conductive metal leads along the first side and the final level includes conductive metal pads with exposed surfaces along the second side. The semiconductor die has conductive features. The semiconductor die is flip chip attached to the first side of the multilevel metallization structure with the conductive features soldered to respective conductive metal pads of the final level of the multilevel metallization structure.

In a further aspect, a method of fabricating an electronic device includes forming a multilevel metallization structure on a semiconductor wafer has an array of unit regions, flip chip attaching a semiconductor die to a respective unit region of the multilevel metallization structure with conductive features of the semiconductor die soldered to respective conductive metal pads of the multilevel metallization structure, forming a package structure that encloses the semiconductor die and a portion of the multilevel metallization structure, removing at least a portion of the semiconductor wafer, and separating an electronic device from the array.

### BRIEF DESCRIPTION OF THE DRAWINGS

FIG. 1 is a perspective view of a packaged electronic device with a die flip chip attached to a multilevel metallization structure.

FIG. 1A is a sectional side elevation view of the electronic device taken along line 1A-1A of FIG. 1.

FIG. 1B is a top plan view of the electronic device of FIGS. 1 and 1A.

FIG. 2 is a flow diagram of a method of fabricating an electronic device.

FIGS. 3-12 are sectional side elevation and top perspective views of the electronic device of FIGS. 1-1B undergoing fabrication according to the method of FIG. 2.

FIG. 13 is a perspective view of a packaged electronic device with a die flip chip attached to a metallization structure.

FIG. 13A is a sectional side elevation view of the electronic device taken along line 13A-13A of FIG. 13.

FIG. 13B is a top plan view of the electronic device of FIGS. 13 and 13A.

FIG. 14 is a flow diagram of a method of fabricating an electronic device.

FIGS. 15-26 are sectional side elevation and top perspective views of the electronic device of FIGS. 13-13B undergoing fabrication according to the method of FIG. 14.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means+/−10 percent of the stated value.

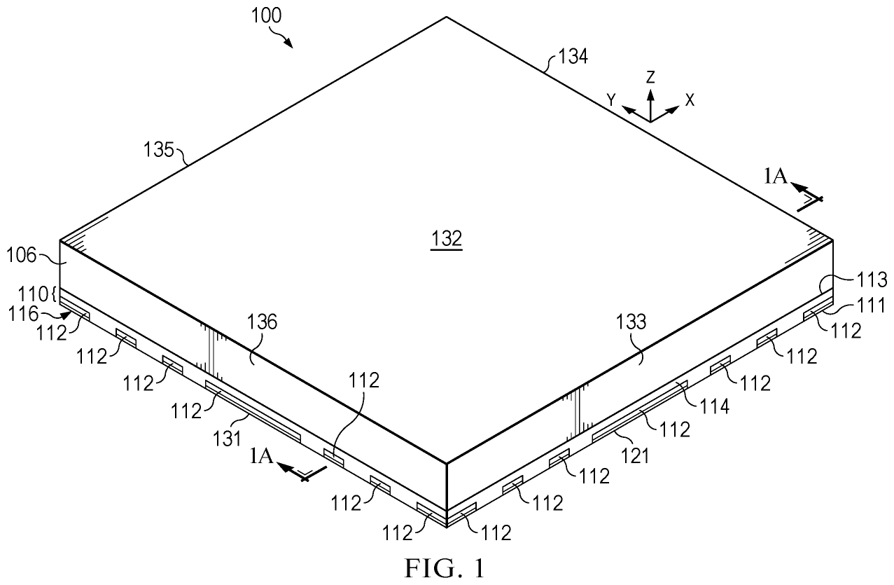

FIGS. 1, 1A, and 1B illustrate a packaged electronic device 100 with a semiconductor die 102 flip chip attached to a silicon wafer based multilevel metallization structure 110. FIG. 1A shows a sectional side view of the electronic device 100 taken along line 1A-1A of FIG. 1, and FIG. 1B shows a top view of the electronic device 100. The electronic device 100 is shown in an example three-dimensional space including a first direction (e.g., X in the illustrated orientation), an orthogonal second direction (e.g., Y), and a third direction (e.g., Z) that is orthogonal to the first and second directions X and Y. A lower side 101 of the semiconductor die 102 has conductive features 104, such as copper or aluminum bond pads, copper pillars or solder balls (e.g., bumps). The electronic device 100 includes a package structure 106 that encapsulates or otherwise encloses the semiconductor die 102 and portions of the multilevel metallization structure 110 to form a quad flat no-lead QFN shape. The conductive features 104 of the semiconductor die 102 are mechanically and electrically coupled to conductive metal pads of the multilevel metallization structure 110 by solder or other adhesive 108.

The multilevel metallization structure 110 has a first (e.g., lower) side 111, a second (e.g., upper) side 113, and multiple levels of conductive metal traces and vias, as well as polyimide insulator material. The individual levels have conductive metal features, such as aluminum or copper, with polyimide insulator material 114 between the conductive metal features. The multilevel metallization structure 110 includes a first level along the first side 111 and a final level along the second side 113. The illustrated example includes further levels between the first level and the final level, and other implementations can have any integer number intermediate levels between the first and final levels. The first level includes conductive metal leads 112 with exposed surfaces along the first side 111. The final level includes conductive metal pads with exposed surfaces along the second side 113. As shown in FIGS. 1 and 1A, the conductive metal leads 112 include indented undercut features 116 along the first side 111. The semiconductor die 102 is flip chip attached to the second side 113 of the multilevel metallization structure 110 with the conductive features 104 soldered (or other conductive attach method) to respective conductive metal pads of the final level of the multilevel metallization structure 110.

The electronic device 100 has a QFN package shape, including a first side 131 (e.g., the lower or bottom side in the illustrated orientation), a second side 132 (e.g., an upper or top side), a third side 133, a fourth side 134, a fifth side 135, and a sixth side 136. The first side 131 extends in a first plane of the first and second directions (e.g., X and Y), the second side 132 extends in a second plane of the first and second directions X and Y, and the second side 132 is spaced apart from the first side 131 along the third direction Z. The lateral sides 133-136 individually extend from the first side 131 to the second side 132 along the third direction Z and the conductive metal leads 112 have second surfaces exposed along respective ones of the sides 133, 134, 135, and 136. In the illustrated example, the conductive metal leads 112, the conductive metal pads, and the traces, vias and other conductive metal features of the multilevel metallization structure 110 are or include copper. In the illustrated example, the conductive metal leads 112 include a solderable finish on the exposed surfaces along the first side 111.

As shown in FIG. 1B, the electronic device 100 includes passive component 140, 141, and 142, such as capacitors, resistors, diodes, inductors etc., as well as an additional semiconductor die 150. In this example, the conductive features 104 of the semiconductor die 102 are soldered (or connected using other methods) to respective ones of a first set of the conductive metal pads of the final level of the multilevel metallization structure 110. The additional die 150 and passive components 140-142 are soldered (or connected using other methods) to respective ones of a second set of the conductive metal pads of the final level of the multilevel metallization structure 110.

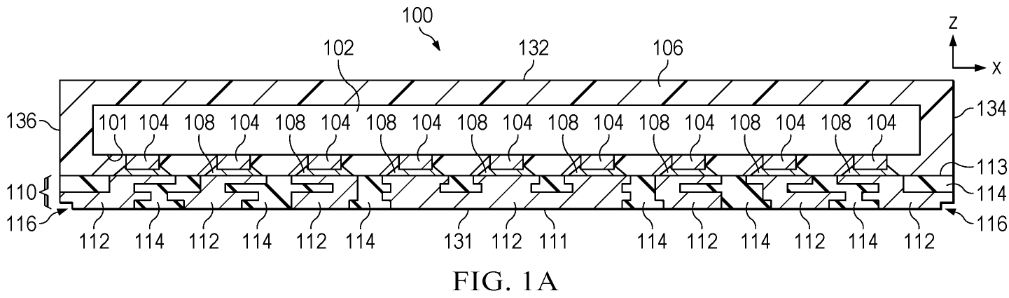

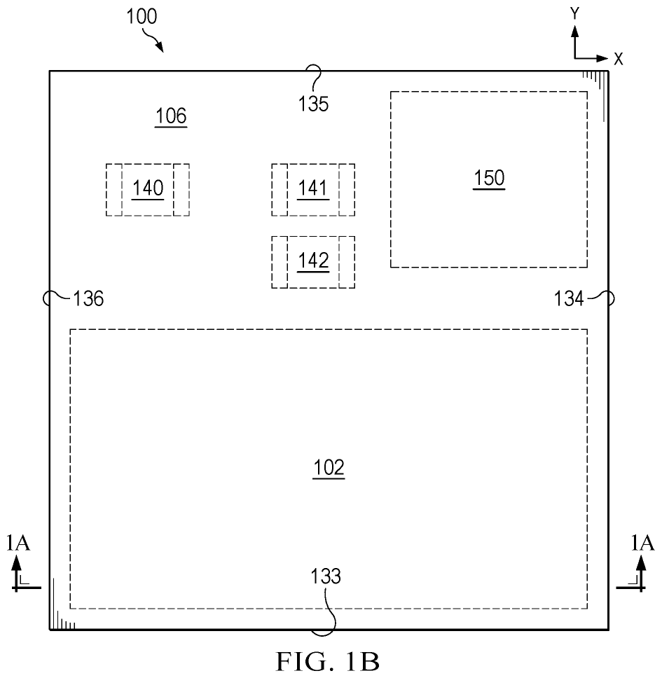

FIG. 2 shows a method 200 of fabricating an electronic device, and FIGS. 3-12 show the electronic device 100 of FIGS. 1-1B undergoing fabrication according to the method 200. The multilevel metallization structure 110 is a wafer-based structure, constructed using back end of the line (BEOL) semiconductor wafer processing to form the conductive metal features including the conductive pads, traces and the leads 112 and polyimide insulation materials 114. The wafer-based multilevel metallization structure 110 allows support for reduced semiconductor die terminal spacing and increased die terminal count as well as improved routing capabilities compared with conventional interconnect substrates or packages, and the multilevel metallization structure 110 facilitates fine lines and spacing to allow routing of leads and interconnect substrate lines to the semiconductor die bumps or terminals 104. In addition, the described examples facilitate use of well-developed semiconductor wafer processing to provide a packaging solution which can be integrated in a single production facility without separate processing for laminated routing substrates and the like.

In one example, the method 200 begins at 202 in FIG. 2 with formation of a protective overcoat oxide layer on a sacrificial semiconductor wafer. FIG. 3 shows one example, in which a process 300 is performed that deposits or otherwise forms the protective overcoat layer 301 on a top side of a silicon wafer 302. In one example, the top side of the wafer 302 is exposed to an oxidizing environment in order to form the oxide protective overcoat layer 301, such as silicon dioxide. Any suitable semiconductor wafer can be used, including an undoped silicon wafer, a silicon-on-insulator (SOI) wafer, or other wafer structure having a semiconductor surface layer, whether silicon or other semiconductor material. The protective overcoat layer can also be realized using alternative methods and materials. In one implementation, moreover, the semiconductor wafer 302 can be a refurbished wafer previously used in a wafer processing facility. In another implementation, the protective overcoat layer formation at 202 is omitted, and further processing proceeds with an uncoated semiconductor wafer 302.

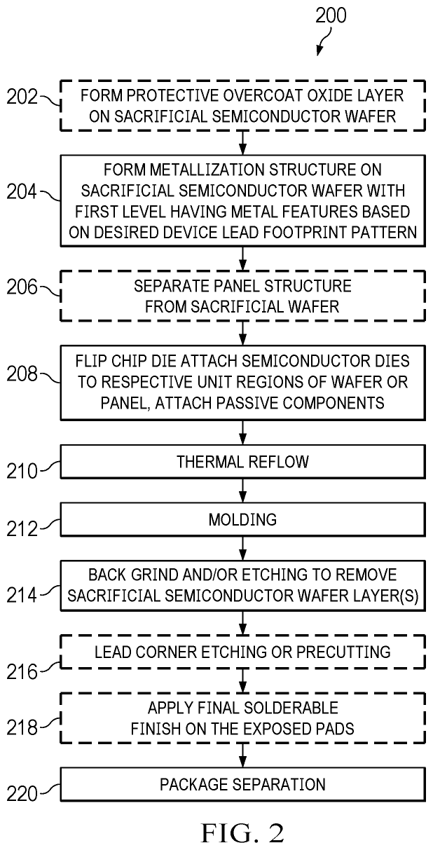

At 204 in FIG. 2, the method 200 includes backend metallization fabrication processing to form a multilevel metallization structure on the semiconductor wafer (e.g., on a top side of the wafer 302 or on any included detective overcoat layer 301). FIG. 4 shows one example, in which a metallization process 400 is performed that forms the above-described multilevel metallization structure 110 on the semiconductor wafer 302. Any suitable backend metallization process 400 can be implemented, for example, using systems and techniques currently employed in fabricating electronic circuits and electrical interconnections therefore in the fabrication of semiconductor dies at the wafer level. In one implementation, the metallization process 400 includes deposition of a pre-metal dielectric (PMD) layer, formation of conductive metal contacts through the PMD layer, for example, by etching openings and blanket deposition of conductive metal, followed by planarization such as chemical mechanical polishing (CMP), and subsequent formation of one or more inter-metal dielectric (ILD) layers with etching of openings, deposition of conductive metal (e.g., copper or metal that includes copper) and chemical mechanical polishing for each subsequently formed level. In another possible implementation, no PMD layer processing is performed, and instead the first level of the multilevel metallization structure 110 is formed by depositing an inter-level dielectric layer directly on the top side of the semiconductor wafer 302 (e.g., or on any included protective overcoat oxide layer 301 as shown in FIG. 4), etching openings in the ILD layer, depositing conductive metal, and chemical mechanical polishing, followed by similar processing for the remaining levels of the multilevel metallization structure 110. In these or other implementations, any suitable dielectric material can be used, such as polyimide 114. In the illustrated implementation, the first level along the first side 111 of the multilevel metallization structure 110 includes the conductive leads 112 having forms that correspond to a desired final lead pattern of the finished packaged electronic device 100 such as a QFN lead pattern with leads 112 along the four lateral sides 133-136, as well as any further desired leads in the interior of the bottom side 111 of the electronic device 100. In addition, the thickness along the third direction Z of the conductive features of the leads 112 in one example is sufficiently thick to accommodate desired lead side wall heights of the finished packaged electronic device 100, including any undercut regions (e.g., 116 in FIGS. 1 and 1A above).

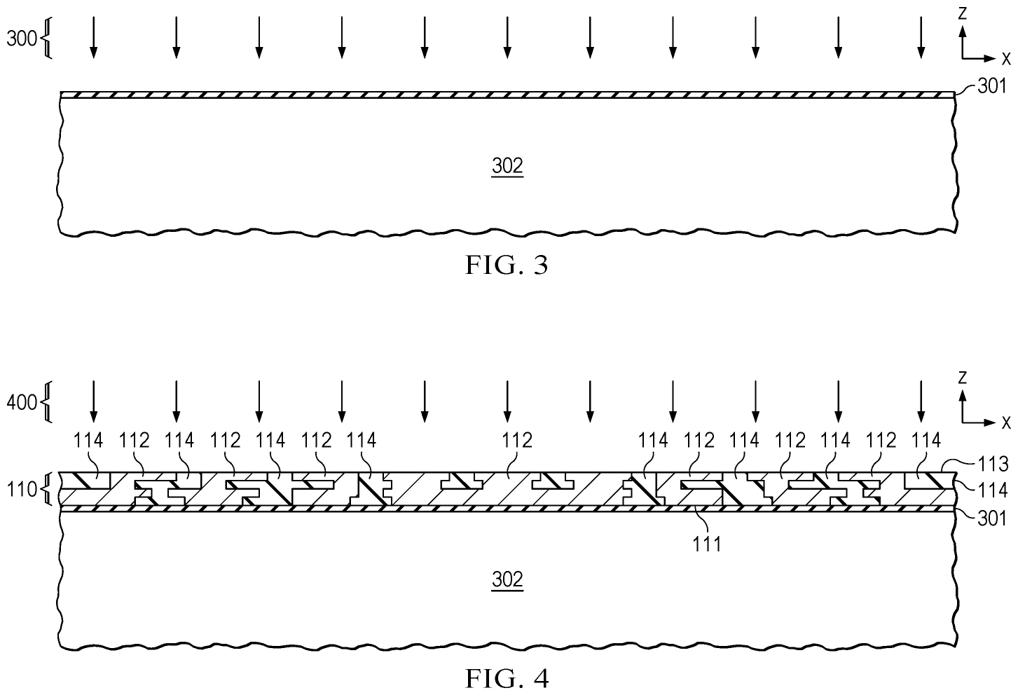

In one example, the method 200 also includes optionally separating a panel structure from the sacrificial semiconductor wafer 302 at 206. FIGS. 5 and 5A show one example, in which a panel separation process 500 is performed (FIG. 5A), such as saw cutting, laser cutting, etc., which separates a panel with an array 504 of unit regions 502 (FIG. 5) from the starting circular wafer 302. As shown in FIG. 5, the wafer 302 has an array of rows and columns of unit regions 502, and the separated panel 504 includes a rectangular panel having a subset array of the unit regions 502 arranged in rows and columns. Separation of the structure into a rectangular array 504 may be beneficial for easy integration into a packaging processing facility, for example, in which die attach pick and place equipment, package molding apparatus, and device separation (e.g., sawing) systems are currently configured to operate on rectangular panels or strips, such as starting lead frame strips, laminated package substrate strips, etc. In another implementation, the panel structure separation at 206 is omitted, and subsequent processing is performed on the starting wafer 302, for example, to more closely integrate the subsequent device packaging steps into a wafer processing system configured to operate on circular or disc-shaped wafers.

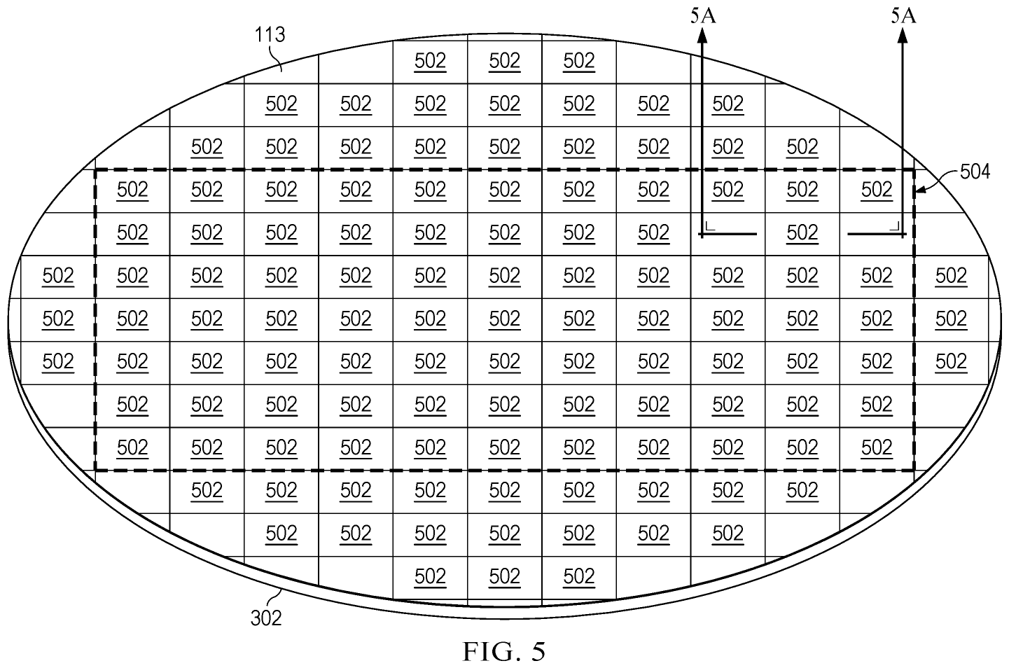

At 208 in FIG. 2, the method 200 continues with flip chip attachment of semiconductor dies to respective unit regions 502 of the wafer or panel, as well as attachment of any included passive components in the respective unit regions 502. FIG. 6 shows one example, in which an automated pick and place component/die attachment process 600 is performed that flip chip die attaches the semiconductor die 102 to the illustrated respective unit region 502 of the multilevel metallization structure 110. The illustrated example also includes flip chip attachment of the second semiconductor die 150 (e.g., FIG. 1B above) and placement of the passive circuit components 140-142 on associated conductive metal pads of the multilevel metallization structure 110 at 208. The attachment process 600 can include an initial step of forming solder paste along the conductive metal pads of the multilevel metallization structure 110 prior to placement of the semiconductor die 102 and other components thereon. In another implementation, the semiconductor die 102 (e.g., and the second semiconductor die 150 and the passive circuit components 140-142) can be provided with solder on the respective conductive features (e.g., bond pads, copper pillars or bumps, passive component leads), such as by dipping or other suitable process, prior to placement on the second side 113 of the multilevel metallization structure 110.

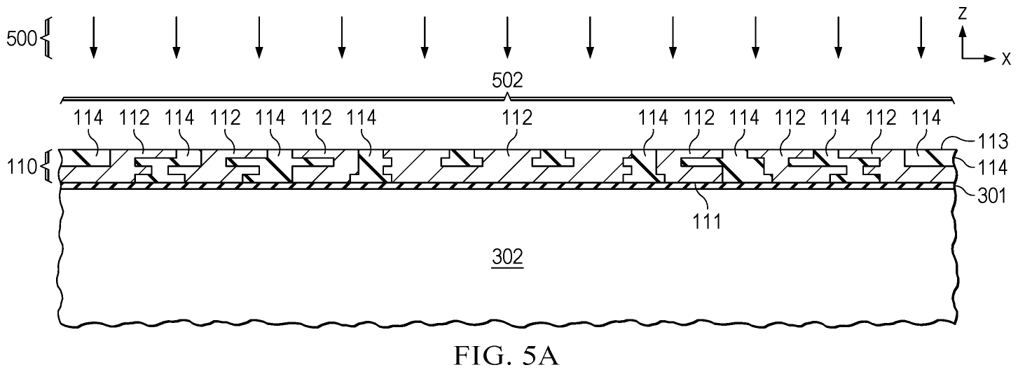

At 210, a thermal reflow process or other curing is performed. FIG. 7 illustrates one example, in which a thermal reflow process 700 is performed that reflows the solder 108 and solders the conductive features 104 of the semiconductor die 102 to a first set of the conductive metal pads of the multilevel metallization structure 110. The process 700 in one example also reflows the solder associated with conductive features of the second semiconductor die 150 and with the conductive terminals of the passive circuit components 140-142 to a second or further set of the conductive metal pads of the multilevel metallization structure 110.

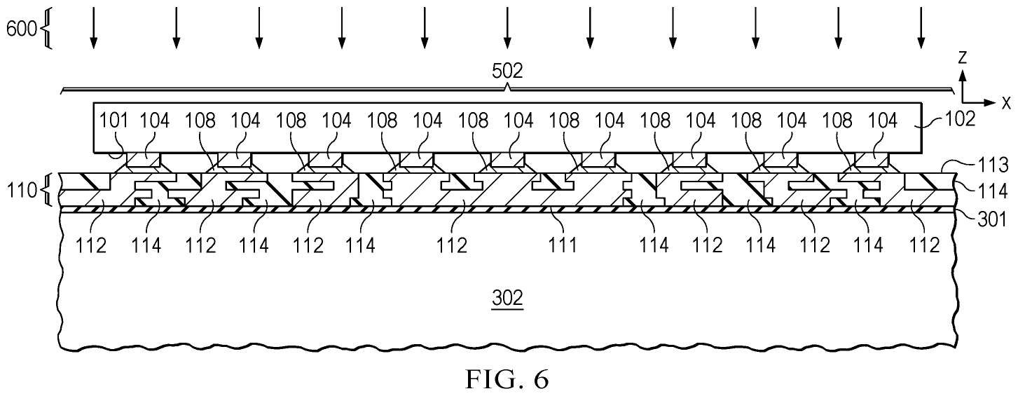

The method 200 continues with molding at 212. FIG. 8 shows one example, in which a molding process 800 is performed, which forms the package structure 106 that encloses the semiconductor die 102 and a portion of the second side 113 of the multilevel metallization structure 110.

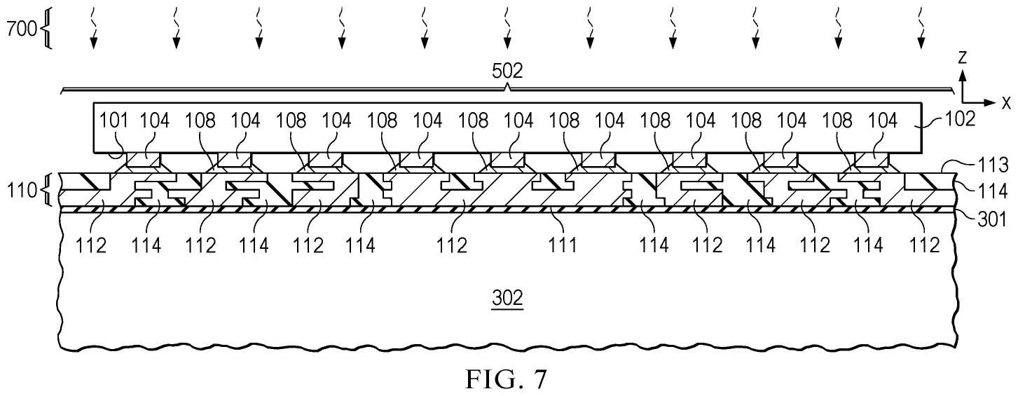

At 214, some or all of the sacrificial semiconductor wafer 302 is removed. FIG. 9 shows one example, in which a process 900 is performed that removes at least a portion of the semiconductor wafer 302. In one example, the process 900 removes all the semiconductor material of the sacrificial semiconductor wafer 302 as shown in FIG. 9. In one implementation, the process 900 is or includes a grinding operation, such as a back grinding operation used in wafer fabrication processes. In this or another example, the process 900 is or includes a chemical etching step or steps. In another implementation, the process 900 includes a combination of grinding and etching. The process 900 exposes the bottom sides of the leads 112 along the first side 111 of the multilevel metallization structure 110, which ultimately function as leads of the finished packaged electronic device 100 as shown in FIGS. 1 and 1A above.

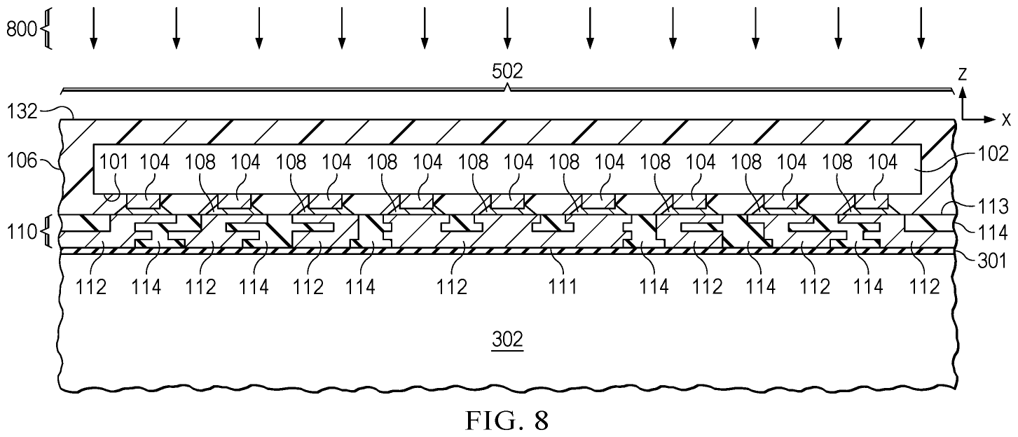

At 216 in FIG. 2, the method 200 further includes forming the indented undercut features 116 along the first side 111 of the multilevel metallization structure 110. FIG. 10 shows one example, in which a process 1000 is performed that forms forming the indented undercut features 116 of the leads 112 along the first side 111 of the multilevel metallization structure 110. In one example, the process 1000 is an etch process using a mask 1002 that exposes the peripheral sides of the exposed leads 112 along the first side 111.

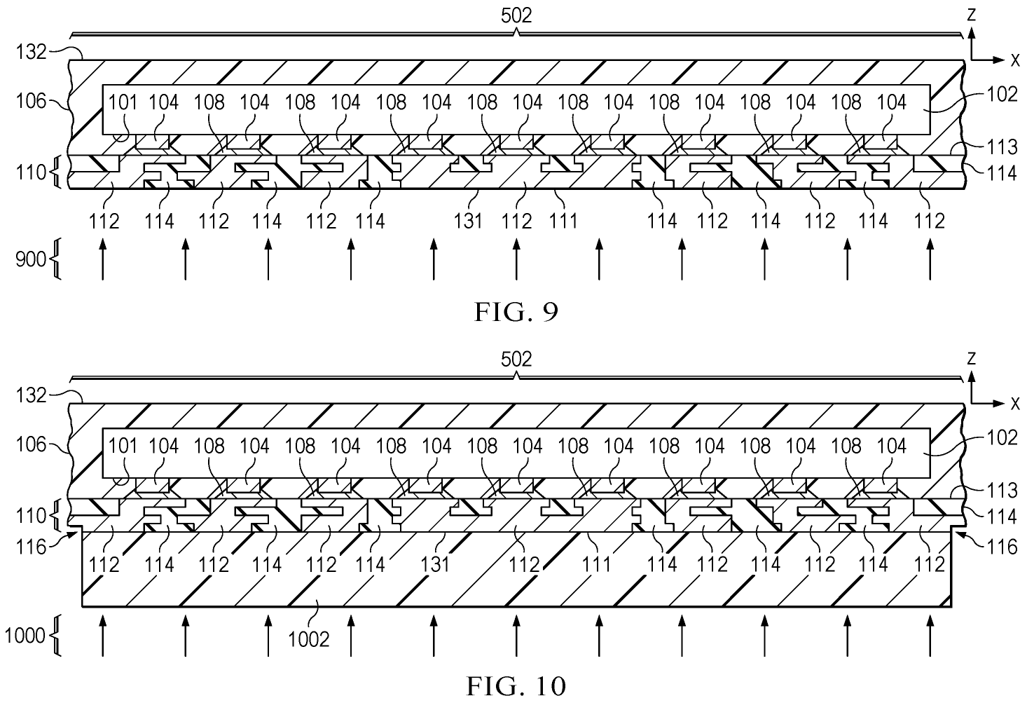

In one implementation, the method 200 further includes application at 218 of a final solderable finish on the exposed leads 112. FIG. 11 shows one example, in which a deposition process 1100 is performed that deposits or otherwise forms a final solderable finish in (not shown) on the exposed bottom sides and indented portions of the leads 112.

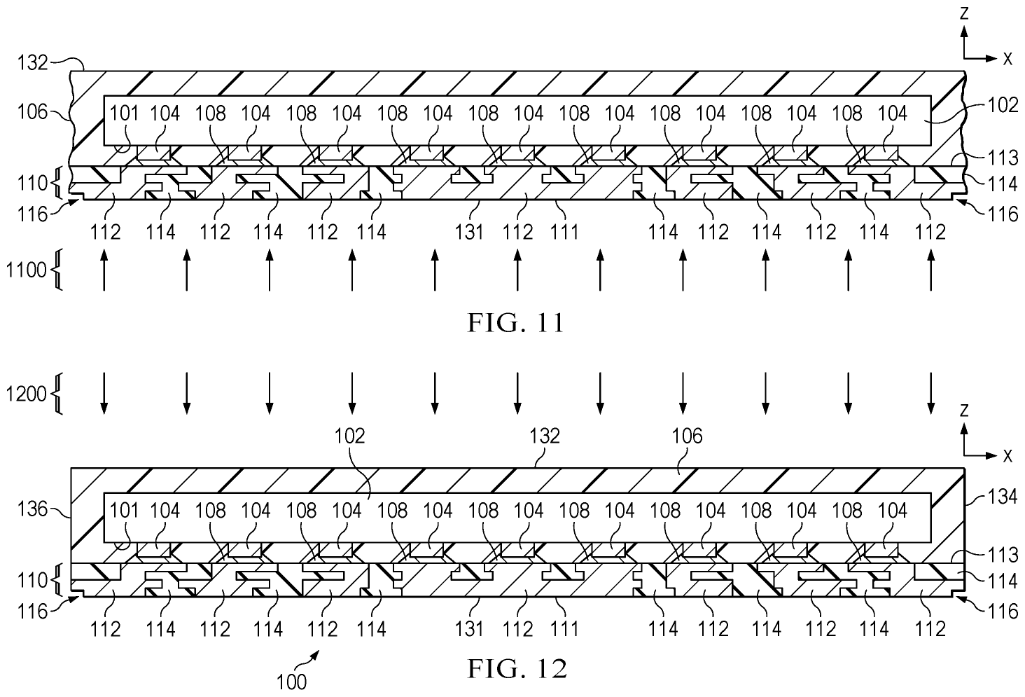

The method 200 also includes package separation processing at 220 in FIG. 2. FIG. 12 shows one example, in which a package separation process 1200 is performed that separates individual packaged electronic devices 100 from the panel or wafer. In one example, the process 1200 is or includes a saw cutting, for example, along first and second direction cutting paths between the individual unit regions 502 (e.g., FIG. 5 above) of the wafer or panel array 504. In another implementation, the process 1200 is or includes laser cutting or etching or combinations of laser or saw cutting and etching processes to separate the individual electronic devices 100 from one another.

The method 200 shows one possible example using backend metallization processing and subsequent removal of remaining portions of the sacrificial semiconductor wafer 302 in order to provide the advantages of small conductive feature sizes and fine pitch feature spacing associated with semiconductor processing in order to facilitate the increased circuit density of advanced semiconductor dies 102. This example provides final device leads 112 fabricated using the metallization processing at 204, portions of which are exposed in the final packaged electronic device 100 to operate as leads for soldering to conductive pads of a host printed circuit board (PCB, not shown).

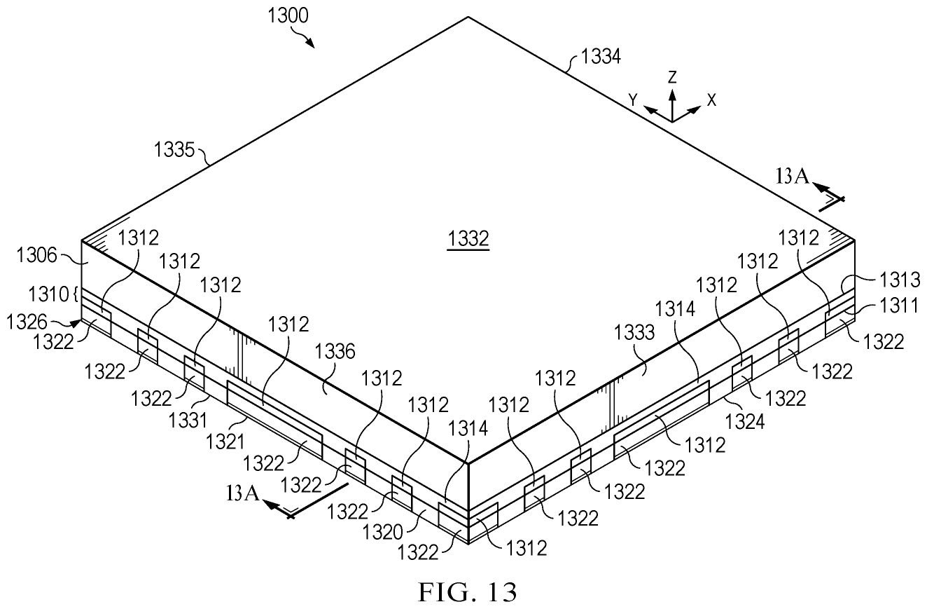

FIGS. 13, 13A, and 13B show another example packaged electronic device 1300, which also benefits from sacrificial semiconductor wafer processing to provide a package substrate with a flip chip attached semiconductor die 1302. FIG. 13 shows a perspective view of the electronic device 13 with the semiconductor die 1302 flip chip attached to a multilevel metallization structure 1310, FIG. 13A shows a sectional side view of the electronic device 1300 taken along line 13A-13A of FIG. 13, and FIG. 13B shows a top view of the electronic device 1300. The electronic device 1300 is shown in an example three-dimensional space including a first direction (e.g., X in the illustrated orientation), an orthogonal second direction (e.g., Y), and a third direction (e.g., Z) that is orthogonal to the first and second directions X and Y.

A lower side 1301 of the semiconductor die 1302 has conductive features 1304, such as copper or aluminum bond pads, solder balls or copper pillars (e.g., bumps). The electronic device 1300 includes a package structure 1306 that encapsulates or otherwise encloses the semiconductor die 1302 and portions of the multilevel metallization structure 1310 to form a quad flat no-lead QFN shape. The conductive features 1304 of the semiconductor die 1302 are mechanically and electrically coupled to conductive metal pads of the multilevel metallization structure 1310 by solder 1308.

The multilevel metallization structure 1310 has a first (e.g., lower) side 1311, a second (e.g., upper) side 1313, and multiple levels of conductive metal traces and vias, as well as polyimide insulator material. The individual levels have conductive metal features, such as aluminum or copper, with polyimide insulator material 1314 between the conductive metal features. The multilevel metallization structure 1310 includes a first level along the first side 1311 and a final level along the second side 1313. The illustrated example includes further levels between the first level and the final level, and other implementations can have any integer number intermediate levels between the first and final levels.

The electronic device 1300 has a semiconductor substrate 1320 with a substrate side 1321 and conductive metal leads 1322 with exposed surfaces along the substrate side 1321. As shown in FIGS. 13 and 13A, the conductive metal leads 1322 include indented undercut features 1326. As discussed further below, the conductive metal leads 1322 are formed in trenches of a starting semiconductor wafer substrate 1320 prior to forming the multilevel metallization structure 1310. This advantageously allows remnant portions of the semiconductor substrate 1320 to operate as heat spreaders for thermal dissipation in operation of the electronic device 1300, where silicon or other semiconductor substrate 1320 provides better thermal dissipation than the insulator material 114 of the multilevel metallization structure 1310 and may enhance thermal performance compared to the approach used in the electronic device 100 of FIGS. 1-1B above.

The first level of the multilevel metallization structure 1310 includes conductive structures 1312 that contact respective ones of the conductive metal leads 1322 along the first side 1311 of the multilevel metallization structure 1310. The final level of the multilevel metallization structure 1310 includes conductive metal pads with exposed surfaces along the second side 1313. The semiconductor die 1302 is flip chip attached to the second side 1313 of the multilevel metallization structure 1310 with the conductive features 1304 soldered to respective conductive metal pads of the final level of the multilevel metallization structure 1310.

The electronic device 1300 has a QFN package shape, including a first side 1331 (e.g., the lower or bottom side in the illustrated orientation), a second side 1332 (e.g., an upper or top side), a third side 1333, a fourth side 1334, a fifth side 1335, and a sixth side 1336. The first side 1331 extends in a first plane of the first and second directions (e.g., X and Y), the second side 1332 extends in a second plane of the first and second directions X and Y, and the second side 1332 is spaced apart from the first side 1331 along the third direction Z. The lateral sides 1333-1336 individually extend from the first side 1331 to the second side 1332 along the third direction Z and the conductive metal leads 1322 have second surfaces exposed along respective ones of the sides 1333, 1334, 1335, and 1336. In the illustrated example, the conductive metal leads 1322, the conductive metal pads, and the traces, vias and other conductive metal features of the multilevel metallization structure 1310 are or include copper. In the illustrated example, the conductive metal leads 1322 include a solderable finish on the exposed surfaces along the first side 1311.

As shown in FIG. 13B, the electronic device 1300 includes passive component 1340, 1341, and 1342, such as capacitors, resistors, diodes, etc., as well as an additional die 1350. In this example, the conductive features 1304 of the semiconductor die 1302 are soldered to respective ones of a first set of the conductive metal pads of the final level of the multilevel metallization structure 1310. The additional die 1350 and passive components 1340-1342 are soldered to respective ones of a second set of the conductive metal pads of the final level of the multilevel metallization structure 1310.

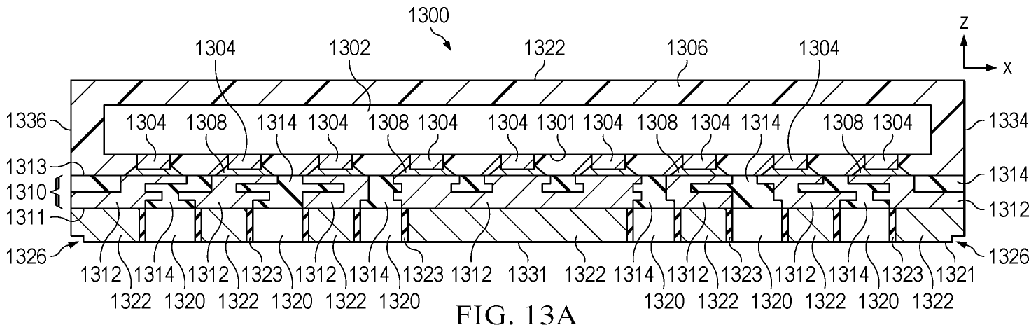

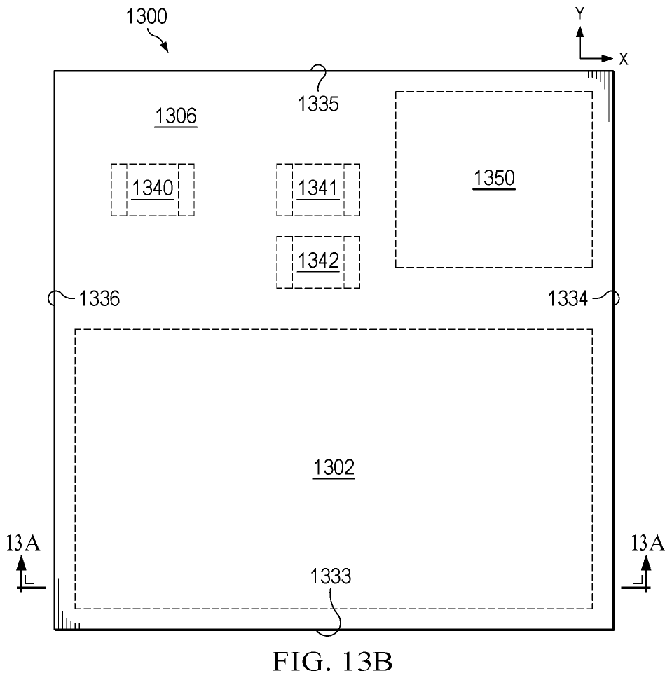

FIG. 14 shows a method 1400 of fabricating an electronic device, and FIGS. 15-26 show the electronic device 1300 of FIGS. 13-13B undergoing fabrication according to the method 1400. The multilevel metallization structure 1310 is a wafer-based structure, constructed using back end of the line (BEOL) semiconductor wafer processing to form the conductive metal features including the conductive pads and the leads 1322 and polyimide insulation materials 1314. The wafer-based multilevel metallization structure 1310 allows support for reduced semiconductor die terminal spacing and increased die terminal count as well as improved routing capabilities compared with conventional interconnect substrates, and the multilevel metallization structure 1310 facilitates fine lines and spacing to allow routing of leads and interconnect substrate lines to the semiconductor die bumps or terminals 1304. In addition, the described examples facilitate use of well-developed semiconductor wafer processing to provide a packaging solution which can be integrated in a single production facility without separate processing for laminated routing substrates and the like.

In addition, the method 1400 includes forming the leads 1322 as conductive material (e.g., that is or includes copper) in trenches of a starting wafer 1320, with semiconductor material (e.g., silicon) between adjacent leads 1322, where the wafer removal processing exposes bottoms of the leads 1322 and leaves remaining semiconductor material between the conductive leads 1322 to operate as heat spreaders in the finished electronic device 1300. The semiconductor substrate 1320 of the electronic device 1300 is described below as a sacrificial or starting wafer 1320, which is subsequently separated during package separation processing, with the remaining portion forming the above-described semiconductor substrate 1320. Any suitable semiconductor wafer 1320 can be used, including an undoped silicon wafer, a silicon-on-insulator (SOI) wafer, or other wafer structure having a semiconductor surface layer, whether silicon or other semiconductor material. In one implementation, moreover, the semiconductor wafer 1320 can be a refurbished wafer previously used in a wafer processing facility.

In one example, the method 1400 begins at 1402 in FIG. 14 with formation of trenches in the sacrificial semiconductor wafer based on a desired device lead footprint pattern. FIG. 15 shows one example, in which an etch process 1500 is performed using an etch mask 1502. The etch process forms trenches 1504 in the top side of the semiconductor wafer 1320, where the trenches 1504 are formed in prospective lead locations of a desired device lead footprint pattern (e.g., a QFN package lead footprint pattern).

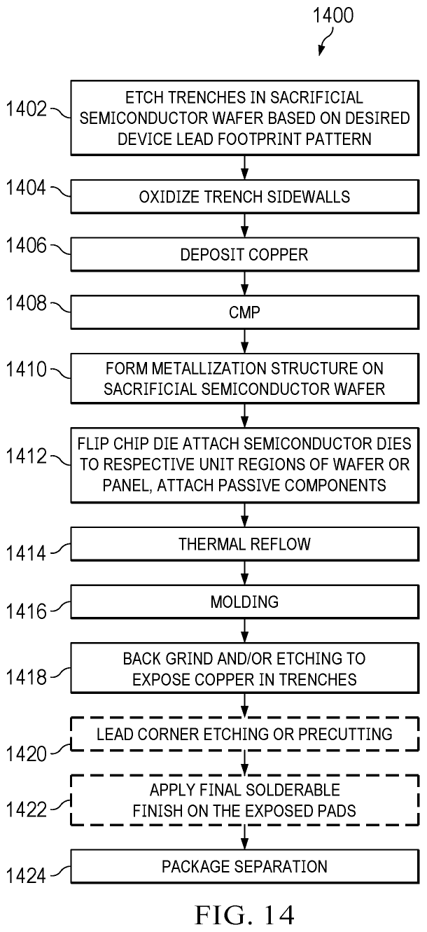

At 1404 in FIG. 14, the method 1400 in one example includes oxidizing the trench sidewalls. FIG. 16 shows one example, in which an oxide formation process 1600 is performed that forms an oxide layer 1323 along the bottom and sidewalls of the trenches 1504. In one example, the process 1600 includes exposing the trenches and the remainder of the top side of the semiconductor wafer 1320 to an oxidizing environment in order to oxidize the silicon or other semiconductor material to form the oxide layer 1323 (e.g., silicon dioxide). The oxide layer 1323 operates as an insulator, which provides electrical isolation between adjacent conductive leads (e.g., leads 1322) subsequently formed in the trenches 1504, in order to enhance the isolation compared with intervening semiconductor material (e.g., silicon) of the semiconductor wafer 1320 between the subsequently formed leads 1322.

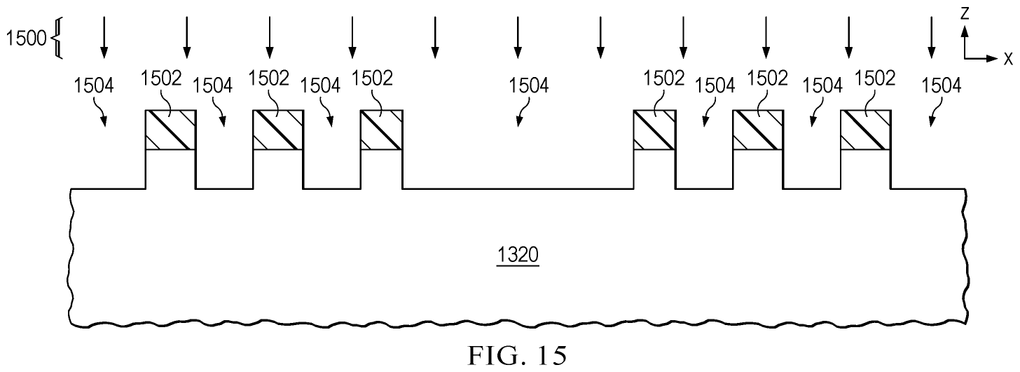

The method 1400 continues at 1406 with deposition of copper or other conductive metal that will ultimately form the conductive leads 1322. FIG. 17 shows one example, in which a deposition process 1700 is performed that deposits copper in the trenches 1504. In one implementation, the process 1700 includes a seed layer deposition step (e.g., chemical vapor deposition or CVD, physical vapor deposition or PVD, plasma enhanced CVD, etc.) to form a copper seed layer in the trenches 1504, followed by copper electroplating to deposit the remainder of the copper material that forms the leads (labeled 1322 and FIG. 17). In the illustrated implementation, the deposition process 1700 fills the trenches and deposition continues above the tops of the trench sidewalls as shown in FIG. 17.

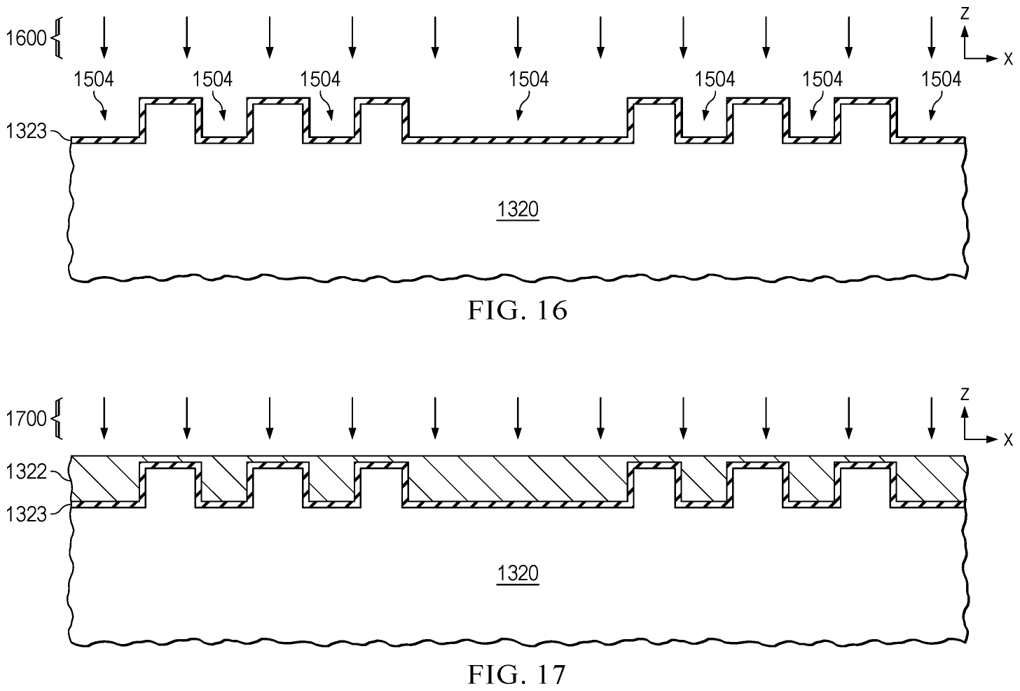

In this example, the method 1400 also includes planarization at 1408. FIG. 18 shows one example, in which a chemical mechanical polishing (CMP) planarization process 1800 is performed that planarizes the top side of the structure, exposing semiconductor material of the semiconductor wafer 1320 between adjacent trenches as shown in FIG. 18.

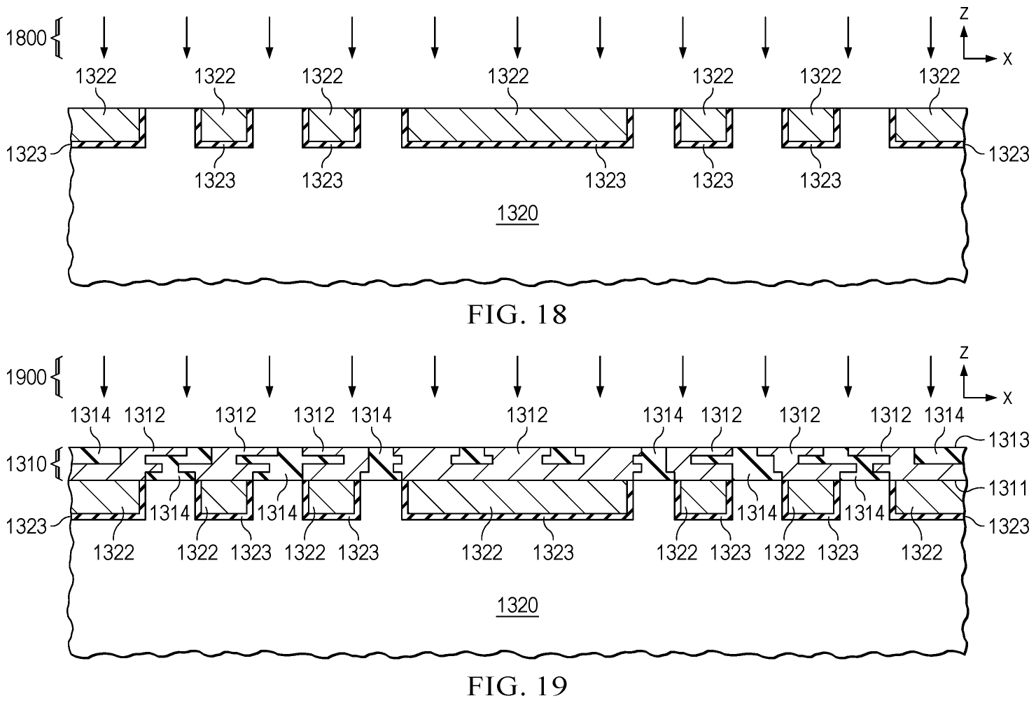

At 1410 in FIG. 14, the method 1400 includes backend metallization fabrication processing to form a multilevel metallization structure on the semiconductor wafer (e.g., on a top side of the wafer 1320 and the leads 1322). FIG. 19 shows one example, in which a metallization process 1900 is performed that forms the above-described multilevel metallization structure 1310 on the semiconductor wafer 1320. Any suitable backend metallization process 1900 can be implemented, for example, using systems and techniques currently employed in fabricating electronic circuits and electrical interconnections therefore in the fabrication of semiconductor dies at the wafer level. In one implementation, the metallization process 1900 includes deposition of a pre-metal dielectric (PMD) layer, formation of conductive metal contacts through the PMD layer, for example, by etching openings and blanket deposition of conductive metal, followed by planarization such as chemical mechanical polishing (CMP), and subsequent formation of one or more inter-metal dielectric (ILD) layers with etching of openings, deposition of conductive metal (e.g., copper or metal that includes copper) and chemical mechanical polishing for each subsequently formed level. In another possible implementation, no PMD layer processing is performed, and instead the first level of the multilevel metallization structure 1310 is formed by depositing an inter-level dielectric layer directly on the top side of the semiconductor wafer 1320 and the conductive leads 1322, etching openings in the ILD layer, depositing conductive metal, and chemical mechanical polishing, followed by similar processing for the remaining levels of the multilevel metallization structure 1310. In these or other implementations, any suitable dielectric material can be used, such as polyimide 1314. In the illustrated implementation, the first level along the first side 1311 of the multilevel metallization structure 1310 includes conductive metal features that correspond to (e.g., at least partially overlie and contact) the conductive leads 1322 (e.g., as well as any further desired leads in the interior of the bottom side 1311 of the electronic device 1300). In one example, the method 1400 also includes optionally separating a panel structure (e.g., FIG. 5 above) from the sacrificial semiconductor wafer 1320 for further processing as a rectangular panel or strip, or the subsequent processing can be performed without such panel separation at the wafer level. The separated panel or the wafer 1320 in one example is processed as an array of unit regions arranged in rows and columns as discussed above.

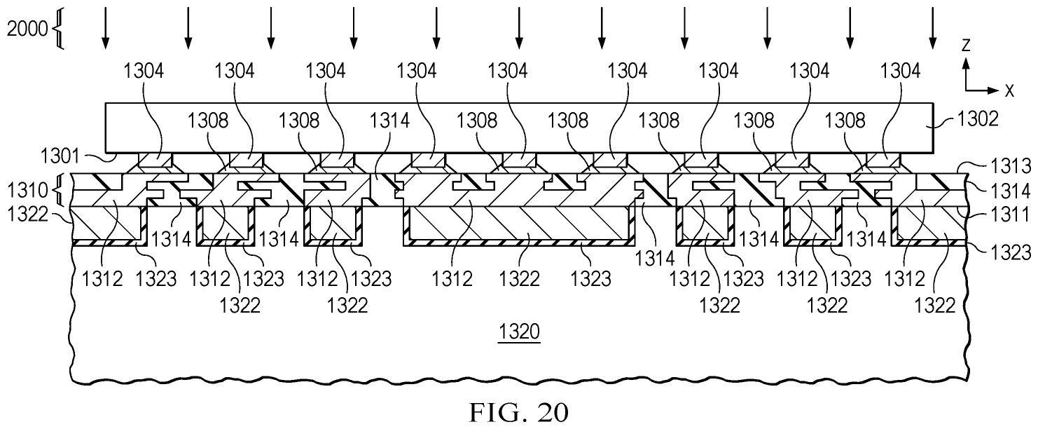

At 1412 in FIG. 14, the method 1400 includes flip chip attachment of semiconductor dies to respective unit regions 502 of the wafer or panel, as well as attachment of any included passive components in the respective unit regions 502. FIG. 20 shows one example, in which an automated pick and place component/die attachment process 2000 is performed that flip chip die attach is the semiconductor die 1302 to the illustrated respective unit region of the multilevel metallization structure 1310. The illustrated example also includes flip chip attachment of the second semiconductor die 1350 (e.g., FIG. 13B above) and placement of the passive circuit components 1340-1342 on associated conductive metal pads of the multilevel metallization structure 1310 at 1412. The attachment process 2000 can include an initial step of forming solder paste 1308 along the conductive metal pads of the multilevel metallization structure 1310 prior to placement of the semiconductor die 1302 and other components thereon. In another implementation, the semiconductor die 1302 (e.g., and the second semiconductor die 1350 and the passive circuit components 1340-1342) can be provided with solder 1308 on the respective conductive features (e.g., bond pads, copper pillars or bumps, passive component leads), such as by dipping or other suitable process, prior to placement on the second side 1313 of the multilevel metallization structure 1310.

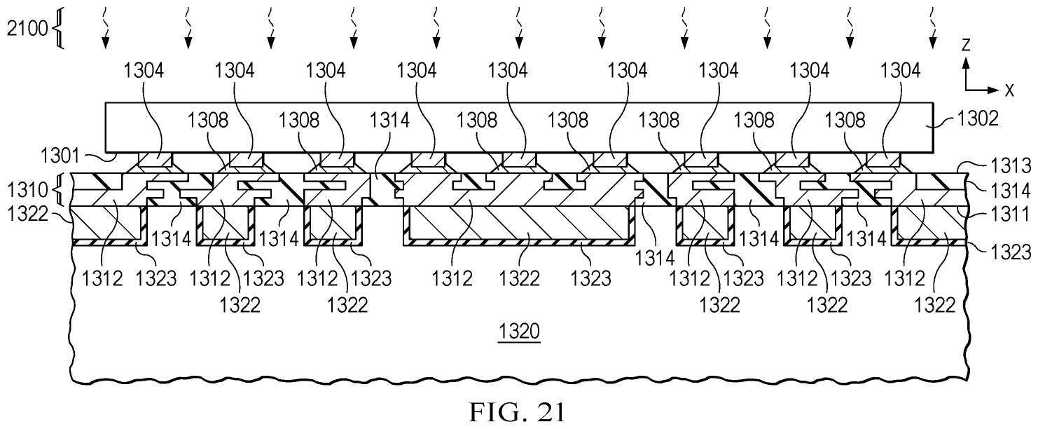

At 1414, a thermal reflow process is performed. FIG. 21 illustrates one example, in which a thermal reflow process 2100 is performed that reflows the solder 1308 and solders the conductive features 1304 of the semiconductor die 1302 to a first set of the conductive metal pads of the multilevel metallization structure 1310. The process 2100 in one example also reflows the solder associated with conductive features of the second semiconductor die 1350 and with the conductive terminals of the passive circuit components 1340-1342 to a second or further set of the conductive metal pads of the multilevel metallization structure 1310.

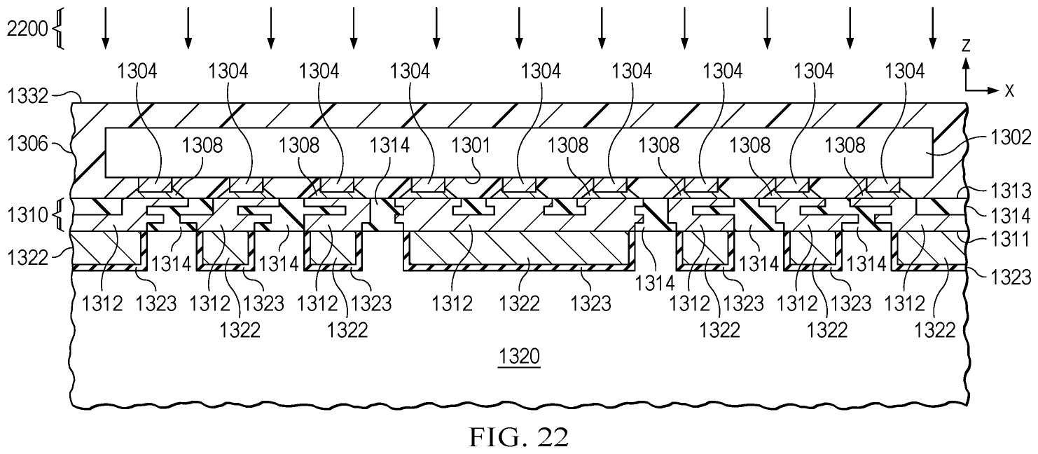

The method 1400 continues with molding at 1416. FIG. 22 shows one example, in which a molding process 2200 is performed, which forms the package structure 1306 that encloses the semiconductor die 1302 and a portion of the second side 1313 of the multilevel metallization structure 1310.

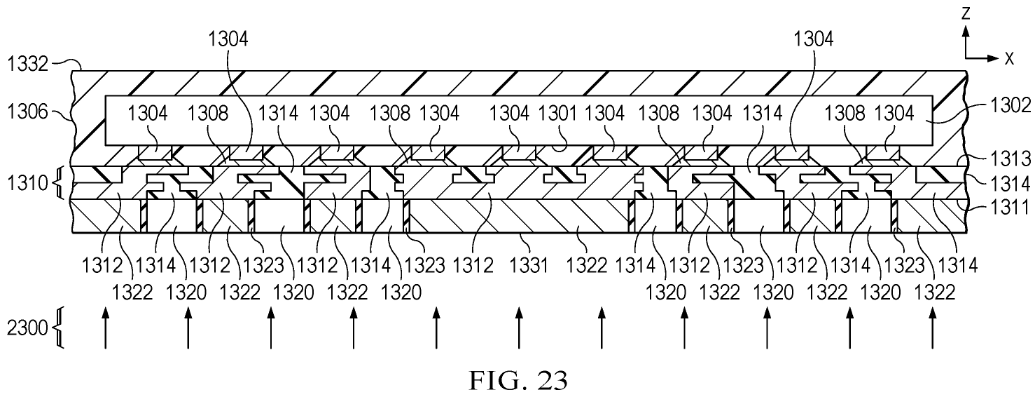

At 1418, some or all of the sacrificial semiconductor wafer 1320 is removed. FIG. 23 shows one example, in which a process 2300 is performed that removes a portion of the semiconductor wafer 1320, as shown in FIG. 23. In one implementation, the process 2300 is or includes a grinding operation, such as a back grinding operation used in wafer fabrication processes. In this or another example, the process 2300 is or includes a chemical etching step or steps. In another implementation, the process 2300 includes a combination of grinding and etching. The process 2300 forms the side 1331 of the substrate 1320 and exposes the bottom sides of the leads 1322 in the trenches of the semiconductor wafer 1320 along the substrate side 1311, which ultimately function as leads of the finished packaged electronic device 1300 as shown in FIGS. 13 and 13A above. In addition, the process 2300 leaves remnant portions of the semiconductor substrate 1320 between adjacent ones of the leads 1322 and the associated trenches, which operate as heat spreaders in the finished electronic device 1300.

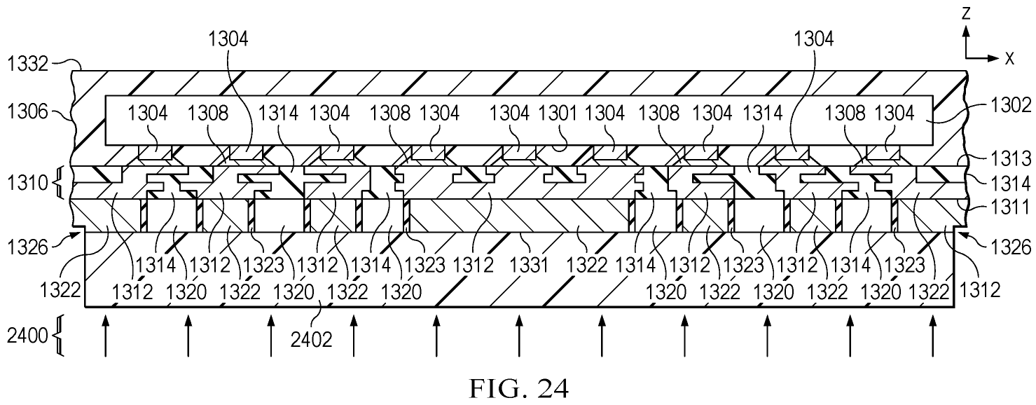

At 1420 in FIG. 14, the method 1400 further includes forming the indented undercut features 1326 along the first side 1311 of the multilevel metallization structure 1310. FIG. 24 shows one example, in which a process 2400 is performed that forms forming the indented undercut features 1326 of the leads 1322 along the side 1331 of the semiconductor substrate 1320. In one example, the process 2400 is an etch process using a mask 2402 that exposes the peripheral sides of the exposed leads 1322 along the substrate side 1331.

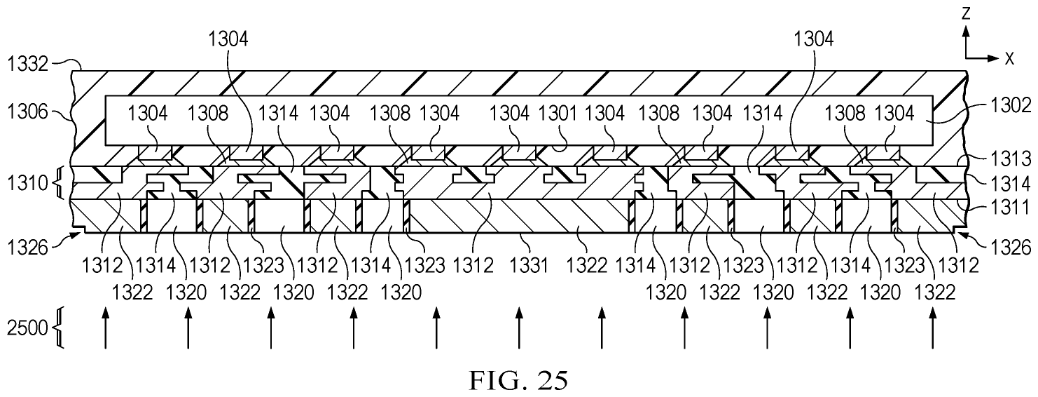

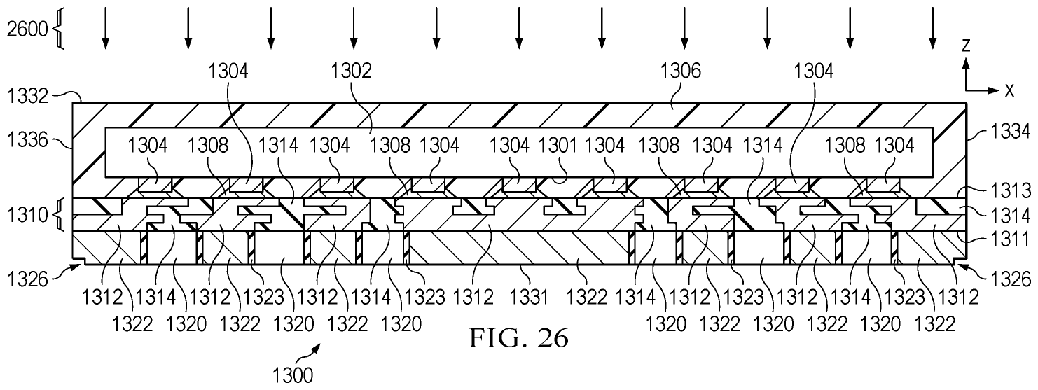

In one implementation, the method 1400 further includes application at 1422 of a final solderable finish on the exposed leads 1322. FIG. 25 shows one example, in which a deposition process 2500 is performed that deposits or otherwise forms a final solderable finish in (not shown) on the exposed bottom sides and indented portions of the leads 1322. The method 1400 also includes package separation processing at 1424 in FIG. 14. FIG. 26 shows one example, in which a package separation process 2600 is performed that separates individual packaged electronic devices 1300 from the panel or wafer. In one example, the process 2600 is or includes a saw cutting, for example, along first and second direction cutting paths between the individual unit regions of the wafer or panel array. In another implementation, the process 2600 is or includes laser cutting or etching or combinations of laser or saw cutting and etching processes to separate the individual electronic devices 1300 from one another.

Modifications are possible in the described examples, and other implementations are possible, within the scope of the claims.

What is claimed is:

1. An electronic device, comprising:
a multilevel metallization structure having multiple levels of conductive metal traces and vias and polyimide insulator material, including a first level along a first side and a final level along a second side, the first level including conductive metal leads with exposed surfaces along the first side, and the final level including conductive metal pads with exposed surfaces along the second side;
a semiconductor die having conductive features, the semiconductor die flip chip attached to the second side of the multilevel metallization structure with the conductive features connected to respective conductive metal pads of the final level of the multilevel metallization structure; and
a package structure that encloses the semiconductor die and portions of the first side of the multilevel metallization structure.

2. The electronic device of claim 1, wherein:
the electronic device has a first side, a second side, a third side, a fourth side, a fifth side, and a sixth side;
the first side extends in a first plane of orthogonal first and second directions;
the second side extends in a second plane of the first and second directions and is spaced apart from the first side along a third direction that is orthogonal to the first and second directions;
the third, fourth, fifth, and sixth sides extend from the first side to the second side along the third direction; and
the conductive metal leads have second surfaces exposed along respective ones of the third, fourth, fifth, and sixth sides.

3. The electronic device of claim 2, wherein the conductive metal leads and the conductive metal pads include copper.

4. The electronic device of claim 2, wherein the electronic device has a quad flat no-lead shape.

5. The electronic device of claim 2, wherein:
the conductive features of the semiconductor die are connected to respective ones of a first set of the conductive metal pads of the final level of the multilevel metallization structure; and
the electronic device further comprises an additional die or a passive component connected to respective ones of a second set of the conductive metal pads of the final level of the multilevel metallization structure.

6. The electronic device of claim 1, wherein the conductive metal leads and the conductive metal pads include copper.

7. The electronic device of claim 1, wherein:
the conductive features of the semiconductor die are connected to respective ones of a first set of the conductive metal pads of the final level of the multilevel metallization structure; and
the electronic device further comprises an additional die or a passive component connected to respective ones of a second set of the conductive metal pads of the final level of the multilevel metallization structure.

8. The electronic device of claim 1, wherein the conductive metal leads include indented undercut features along the first side.

9. The electronic device of claim 1, wherein the conductive metal leads include a solderable finish on the exposed surfaces along the first side.

10. An electronic device, comprising:
a semiconductor substrate having a substrate side and conductive metal leads with exposed surfaces along the substrate side;
a multilevel metallization structure having multiple levels of conductive metal traces and vias and polyimide insulator material, including a first level along a first side and a final level along a second side, the first level including conductive structures that contact respective ones of the conductive metal leads along the first side, and the final level including conductive metal pads with exposed surfaces along the second side;
a semiconductor die having conductive features, the semiconductor die flip chip attached to the second side of the multilevel metallization structure with the conductive features connected to respective conductive metal pads of the final level of the multilevel metallization structure; and
a package structure that encloses the semiconductor die and portions of the first side of the multilevel metallization structure.

11. The electronic device of claim 10, wherein:
the electronic device has a first side, a second side, a third side, a fourth side, a fifth side, and a sixth side;
the first side extends in a first plane of orthogonal first and second directions;
the second side extends in a second plane of the first and second directions and is spaced apart from the first side along a third direction that is orthogonal to the first and second directions;
the third, fourth, fifth, and sixth sides extend from the first side to the second side along the third direction; and
the conductive metal leads have second surfaces exposed along respective ones of the third, fourth, fifth, and sixth sides.

12. The electronic device of claim 11, wherein the electronic device has a quad flat no-lead shape.

13. The electronic device of claim 10, wherein the conductive metal leads and the conductive metal pads include copper.

14. The electronic device of claim 10, wherein:
the conductive features of the semiconductor die are connected to respective ones of a first set of the conductive metal pads of the final level of the multilevel metallization structure; and
the electronic device further comprises an additional die or a passive component connected to respective ones of a second set of the conductive metal pads of the final level of the multilevel metallization structure.

15. The electronic device of claim 10, wherein the conductive metal leads include indented undercut features along the first side.

16. The electronic device of claim 10, wherein the conductive metal leads include a solderable finish on the exposed surfaces along the first side.

17. A method of fabricating an electronic device, the method comprising:
forming a multilevel metallization structure on a semiconductor wafer having an array of unit regions;
flip chip attaching a semiconductor die to a respective unit region of the multilevel metallization structure with conductive features of the semiconductor die connected to respective conductive metal pads of the multilevel metallization structure;
forming a package structure that encloses the semiconductor die and a portion of the multilevel metallization structure;
removing at least a portion of the semiconductor wafer; and
separating an electronic device from the array.

18. The method of claim 17, wherein removing at least a portion of the semiconductor wafer includes:
removing all of the semiconductor wafer to expose conductive metal leads along a first side of the multilevel metallization structure.

19. The method of claim 17, wherein removing at least a portion of the semiconductor wafer includes:
removing a portion of the semiconductor wafer to expose conductive metal leads in trenches of the semiconductor wafer and to expose a remaining portion of the semiconductor wafer between the trenches.

20. The method of claim 17, further comprising:
attaching an additional die or a passive component to the respective unit region of the multilevel metallization structure with terminals of the additional die or passive component connected to further conductive metal pads of the multilevel metallization structure.
